(19) United States
(12) Patent Application Publication
(10) Pub. No.: US 2013/0213931 A1
(43) Pub. Date: Aug. 22, 2013

(54) METHOD FOR FORMING A PATTERN, METHOD FOR PRODUCING A SUBSTRATE, AND METHOD FOR PRODUCING A MOLD

(71) Applicant: FUJIFILM Corporation, (US)

(72) Inventor: Tomokazu UMEZAWA, Minamiashigara-shi (JP)

(73) Assignee: FUJIFILM Corporation, Tokyo (JP)

(21) Appl. No.: 13/850,667

(22) Filed: Mar. 26, 2013

Related U.S. Application Data
(63) Continuation of application No. PCT/JP2011/005381, filed on Sep. 26, 2011.

(30) Foreign Application Priority Data
Sep. 27, 2010 (JP) 2010-214936

(51) Int. Cl. G03F 7/36

(52) U.S. Cl. CPC G03F 7/36
USPC 216/49; 430/326

(57) ABSTRACT

A method for forming a pattern is provided. A photoresist layer constituted by organic dye, which is capable of deformation in a heat mode, is formed on a substrate. A laser beam is irradiated onto the photoresist layer, to form hole portions in the photoresist layer at portions onto which the laser beam is irradiated. The photoresist layer is etched within a vacuum using a predetermined gas, following the step in which the hole portions are formed in the photoresist layer.

### TECHNICAL FIELD

The present invention is related to a method for forming a pattern. More specifically, the present invention is related to a method for forming a pattern by irradiating a laser beam onto a photoresist layer which is capable of deformation in a heat mode. The present invention is also related to a method for producing a substrate having a pattern of protrusions and recesses on the surface thereof, formed by such a method for forming a pattern. Further, the present invention is related to a method for producing a mold from a pattern formed by the method for forming a pattern.

### BACKGROUND ART

There are known methods for forming patterns of fine protrusions and recesses that employ photoresist layers which are capable of deformation in a heat mode (refer to Japanese Unexamined Patent Publication No. 2009-277335, for example). In such a method for forming a pattern, first, a photoresist layer capable of deformation in a heat mode is formed on a substrate, and then a laser beam is irradiated onto the photoresist layer. The portions of the photoresist layer which are irradiated by the laser beam are lost by the energy of the laser beam, and hole portions (recesses) are formed in the photoresist layer. This method for forming a pattern enables simplification of production steps, because a development step is obviated.

In the method for forming a pattern described above, the hole portions are formed by chemical and/or physical changes such as dissolution, sublimation, vaporization, and scattering. Therefore, it is known that foreign matter is generated during these changes (refer to Japanese Unexamined Patent Publication No. 2009-117019, for example). In view of this problem, the invention of Japanese Unexamined Patent Publication No. 2009-117019 removes the foreign matter employing a liquid that does not react with the photoresist layer after the hole portions are formed. Favorable protrusive and recessed shapes can be formed when etching is performed using the photoresist layer as a mask to form recesses in the surface of the substrate following the cleansing step, by performing cleansing using such a liquid.

### DISCLOSURE OF THE INVENTION

However, in the technique disclosed in Japanese Unexamined Patent Publication No. 2009-117019, there is a problem that the liquid employed to remove foreign matter (cleansing) seeps into the photoresist layer. The liquid which is employed to remove the foreign matter does not react with the photoresist layer. However, if the liquid seeps through the photoresist layer to the interface between the photoresist layer and the substrate, problems, such as the surface of the substrate being damaged and the photoresist layer and the substrate becoming likely to separate, will occur.

The present invention has been developed in view of the foregoing circumstances. It is an object of the present invention to provide a method for forming a pattern that enables foreign matter, which is generated during formation of hole portions, to be removed while suppressing damage to a substrate. Additional objects of the present invention are to provide a method for forming a substrate and a method for forming a mold that utilizes the method for forming a pattern.

To achieve the above object, the present invention provides a method for forming a pattern, comprising the steps of:

forming a photoresist layer constituted by organic dye, which is capable of deformation in a heat mode, on a substrate;

irradiating a laser beam onto the photoresist layer, to form hole portions in the photoresist layer at portions onto which the laser beam is irradiated; and

etching the photoresist layer within a vacuum using a predetermined gas following the step of forming the hole portions.

In the method for forming a pattern of the present invention, the amount of etching performed during the etching step may be determined according to the thickness of the photoresist layer at the hole portions.

The method for forming a pattern may further comprise: a measuring step that measures the thickness of the photoresist layer at the hole portions, and the amount of etching may be determined based on the thickness measured in the measuring step. In this case, the measuring step may measure the thickness of the photoresist layer at the hole portions at a plurality of measurement points and calculate an average value of the thickness of the photoresist layer at the plurality of measurement points, and the amount of etching may be determined based on the calculated average value.

The amount of etching may be determined to be a value 1.05 times or greater than the average value. Alternatively, the amount of etching may be determined to be a value 1.2 times or greater than the average value.

The fluctuation in the thickness of residual film may be calculated based on the maximum value and the minimum value of the thickness of the photoresist layer measured at the plurality of measurement points in the measuring step, and the amount of etching may be determined based on the average value and the fluctuation in the thickness of residual film.

As an alternative to the above, the measuring step may measure the thickness of the photoresist layer at the hole portions at a plurality of measurement points, and the amount of etching may be determined based on the maximum value of the thickness of the photoresist layer measured at the plurality of measurement points.

In the method for forming a pattern of the present invention, the substrate may be a Si substrate, and the predetermined gas may be a gas that contains O₂.

It is preferable for the method for forming a pattern of the present invention to be of a configuration, wherein:

the etching step removes foreign matter which is generated by the laser beam being irradiated onto the photoresist layer when the hole portions are formed.

The present invention also provides a method for producing a substrate having a pattern of protrusions and recesses, comprising the steps of:

forming a photoresist layer constituted by organic dye, which is capable of deformation in a heat mode, on a substrate;

irradiating a laser beam onto the photoresist layer, to form hole portions in the photoresist layer at portions onto which the laser beam is irradiated;

etching the photoresist layer within a vacuum using a predetermined gas following the step of forming the hole portions, to expose the surface of the substrate at the hole portions; and

performing plasma etching using the photoresist layer as a mask to form a pattern of protrusions and recesses on the surface of the substrate, following the step of exposing the surface of the substrate.

The method for producing a substrate having a pattern of protrusions and recesses of the present invention may further comprise: a step that etches the photoresist layer within a vacuum using a predetermined gas to remove the photoresist layer from the substrate, following the step of forming the pattern of protrusions and recesses on the surface of the substrate.

The substrate may be a Si substrate, and a gas that contains SF₆ may be used to perform plasma etching in the step of forming the pattern of protrusions and recesses on the surface of the substrate.

Further, the present invention provides a method for producing a mold, comprising the steps of:

forming a photoresist layer constituted by organic dye, which is capable of deformation in a heat mode, on a substrate, to produce a photoresist structure;

irradiating a laser beam onto the surface of the photoresist structure toward the side of the photoresist layer, to form hole portions in the photoresist layer at portions onto which the laser beam is irradiated;

etching the surface of the photoresist structure toward the side of the photoresist layer within a vacuum using a predetermined gas following the formation of the hole portions, to remove foreign matter which is generated by the laser beam being irradiated onto the photoresist layer when the hole portions are formed; and

employing the photoresist structure as an original plate to transfer a pattern of protrusions and recesses formed on the original plate to the mold.

The method for producing a mold of the present invention may adopt a configuration, wherein:

the step of etching the photoresist layer exposes the surface of the substrate at the hole portions; and the method further comprises the step of:

performing plasma etching using the photoresist layer as a mask to form a pattern of protrusions and recesses on the surface of the substrate, between the step of etching the photoresist layer and the step of transferring the pattern of protrusions and recesses to the mold.

In addition to the above, the method for producing a mold of the present invention may further comprise:

a step that etches the photoresist layer within a vacuum using a predetermined gas to remove the photoresist layer from the substrate, between the step of forming the pattern of protrusions and recesses on the surface of the substrate and the step of transferring the pattern of protrusions and recesses to the mold.

The method for forming a pattern of the present invention irradiates a laser beam onto a photoresist layer which is formed on a substrate to form hole portions, then performs gas etching on the photoresist layer thereafter. Foreign matter, which is generated when the laser beam is irradiated to form the hole portions, can be removed by the gas etching. The present invention employs a dry etching technique to remove foreign matter, and can suppress the damage caused to the substrate when removing the foreign matter, compared to cases in which a liquid is employed to remove the foreign matter. In addition, when a plurality of hole portions are formed in the photoresist layer and gas etching is performed with respect to the photoresist layer to expose the substrate at at least a portion of the plurality of hole portions, fluctuations in the depths of the hole portions can be suppressed. Particularly in the case that the amount of etching performed by the gas etching is determined such that the substrate is exposed at all of the hole portions, the depths of the hole portions can be made substantially uniform.

The method for producing a substrate of the present invention can produce a substrate having a pattern of protrusions and recesses which is formed by utilizing the method for forming a pattern of the present invention. In addition, the method for producing a mold of the present invention can produce a mold having a pattern corresponding to a pattern of protrusions and recesses which is formed by utilizing the method for forming a pattern of the present invention.

### BRIEF DESCRIPTION OF THE DRAWINGS

FIG. 1A is a sectional diagram that illustrates a step of a method for forming a pattern according to a first embodiment of the present invention.

FIG. 1B is a sectional diagram that illustrates a step of the method for forming a pattern according to the first embodiment of the present invention.

FIG. 1C is a sectional diagram that illustrates a step of the method for forming a pattern according to the first embodiment of the present invention.

FIG. 1D is a sectional diagram that illustrates a step of the method for forming a pattern according to the first embodiment of the present invention.

FIG. 1E is a sectional diagram that illustrates a step of the method for forming a pattern according to the first embodiment of the present invention.

FIG. 2 is a table that illustrates the results of evaluations regarding removal of foreign matter.

FIG. 3A is a sectional diagram that illustrates a step of a method for producing a substrate according to a third embodiment of the present invention.

FIG. 3B is a sectional diagram that illustrates a step of the method for producing a substrate according to the third embodiment of the present invention.

FIG. 3C is a sectional diagram that illustrates a step of the method for producing a substrate according to the third embodiment of the present invention.

FIG. 3D is a sectional diagram that illustrates a step of the method for producing a substrate according to the third embodiment of the present invention.

FIG. 4 is a table that illustrates the results of evaluations regarding fluctuations in the depths of recesses formed in substrates.

FIG. 5A is a sectional diagram that illustrates a step of a method for producing a mold according to a fourth embodiment of the present invention.

FIG. 5B is a sectional diagram that illustrates a step of the method for producing a mold according to the fourth embodiment of the present invention.

### BEST MODE FOR CARRYING OUT THE INVENTION

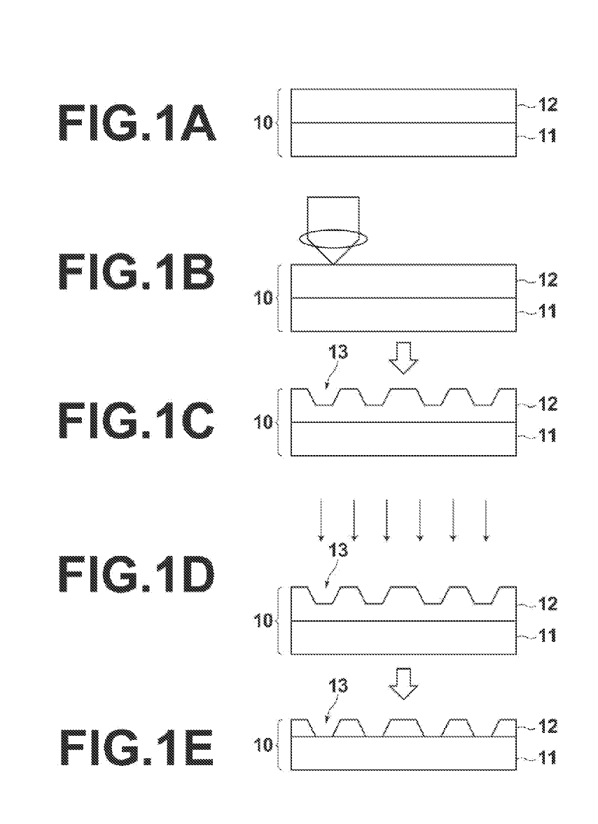

Hereinafter, embodiments of the present invention will be described in detail with reference to the attached drawings. A first embodiment of the present invention is related to a method for forming a pattern on a photoresist layer. FIG. 1A through FIG. 1E illustrate the steps for forming a pattern. A photoresist layer 12 having a predetermined film thickness is formed on a substrate 11 (FIG. 1A). A silicon substrate is employed as the substrate 11, for example. An organic dye which is capable of deformation in a heat mode is employed as the material of the photoresist layer 12. In greater detail, a material that deforms due to heat, which intense light is converted to when the light is irradiated, to enable formation of hole portions is employed. Examples of the material of the photoresist layer 12 include recording materials which are employed in the recording layers of recordable optical recording media.

The substrate 11 and the photoresist layer 12 constitute a photoresist structure 10. A laser beam is focused on the surface of the photoresist structure having the photoresist layer 12 thereon (FIG. 1B), and the laser forms hole portions 13 at the irradiated portions (FIG. 1C). The wavelength of the laser beam which is employed at this time may be selected as appropriate according to the material which is employed in the photoresist layer 12. In addition, the power of the laser and the line speed during scanning of the laser may be set as appropriate according to the desired depth of the hole portions and the like. The laser beam is irradiated onto desired positions of the photoresist layer 12, and a desired pattern of protrusions and recesses is formed on the photoresist layer 12. At this time, foreign matter (not shown) is generated on the photoresist layer 12 when the hole portions 13 are formed.

Next, the surface of the photoresist structure 10 having the photoresist layer 12 thereon is etched within a vacuum using a predetermined gas (FIG. 1D). A gas that does not react with the substrate 11 is employed to perform the etching. For example, O₂ gas may be employed in the case that a silicon substrate is employed as the substrate 11. The film thickness of the photoresist layer 12 decreases as a whole due to the gas etching being performed (FIG. 1E). At this time, the foreign matter which was generated when the hole portions 13 were formed are removed.

The reason why the foreign matter is removed by gas etching is considered as follows. That is, the foreign matter which is generated when the laser beam is irradiated onto the photoresist layer 12 is considered to be generated by the material of the photoresist layer 12 transforming due to heat and the like, and thought to be lower molecules compared to the material of the photoresist layer 12. The film thickness of the photoresist layer 12 decreases as a whole by performing O₂ plasma etching on the photoresist layer 12, the lower molecule foreign matter separates from the photoresist layer 12, and the foreign matter is removed.

The present inventors conducted experiments to confirm the degrees to which foreign matter can be removed under a plurality of etching conditions, to confirm the foreign matter removing effect of gas etching. In these experiments, a silicon substrate (100) having a thickness of 0.5 mm was employed as the substrate 11. A dye material (oxonol dye) having a composition indicated by the chemical formula below was employed as the photoresist layer 12. 2 grams of the dye material was diluted in 100 ml of a TFP (Tetra Fluoro Propanol) solution, and coated onto the silicon substrate by the spin coat method. The thickness of the dye resist layer formed by the spin coat method was 110 nm.

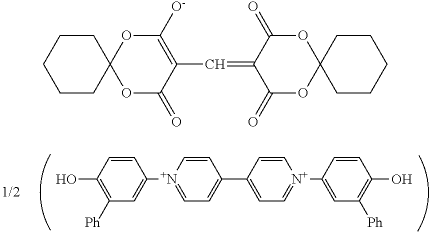

Next, laser exposure was performed on the surface of the dye resist structure having the dye resist layer thereon using NEO 1000 (wavelength: 405 nm, NA: 0.85) by Pulsetec Industrial, Co., Ltd. The laser exposure conditions were as follows.
Laser Feeding Pitch: 0.2 μm
Line Speed: 5 m/s
Recording Signal: 25 MHz Rectangular Waveform (Duty Ratio: 20%)
Laser Output: 3.5 mW

A plurality of samples of the dye resist structure were produced and underwent the laser exposure described above. O₂ plasma etching was administered onto each of the produced samples with an etching apparatus (EXAM by Shinko Seiki) for different etching times. The etching conditions were as follows.
Injection Power: 50 W
O₂ Gas Flow Rate: 100 sccm (Pressure: 18 Pa)
Etching Time: 10 seconds to 70 seconds (10 second increments)

The surface of the dye resist layer of each dye resist structure (each sample) was observed with an AFM (Atomic Force Microscope; Nanoscope V by Japan Veeco) to count the number of pieces of foreign matter as an evaluation. The observation regions were 2 μm by 2 μm areas. This observation was also performed for a dye resist structure on which O₂ etching was not administered following laser exposure.

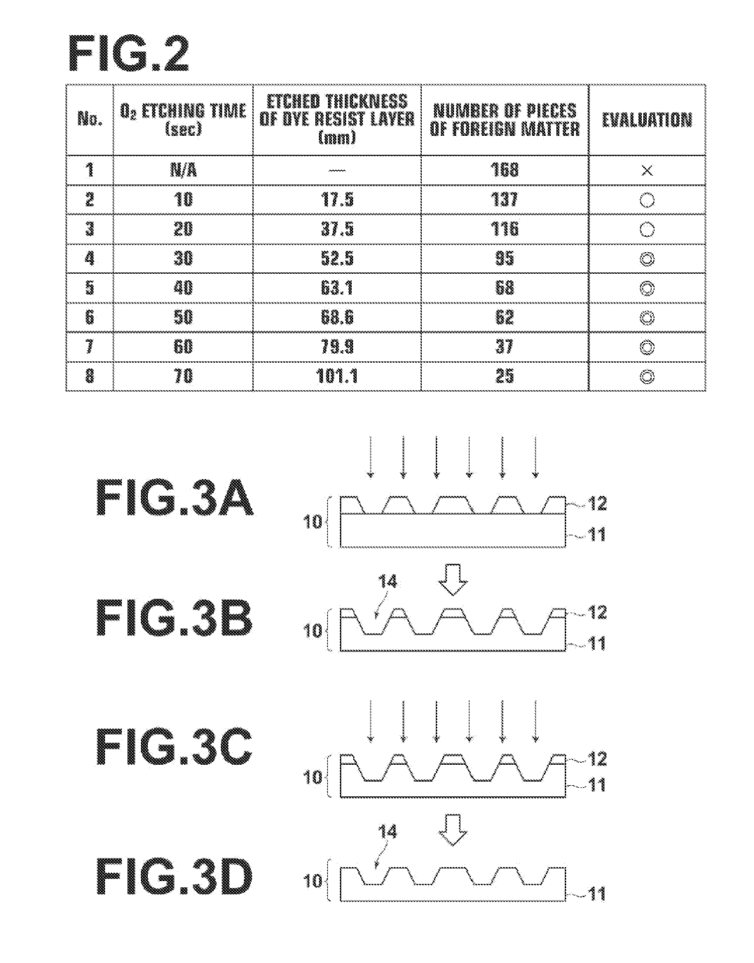

FIG. 2 shows the results of evaluation. The number of pieces of foreign matter was 168 in the sample that did not undergo O₂ etching (No. 1 in the table of FIG. 2). In the sample that underwent O₂ etching for 10 seconds (No. 2), the etched thickness of the dye resist layer was 17.5 mm. That is, the film thickness of the dye resist layer decreased by 17.5 mm. At this time, the number of pieces of foreign matter was 137. The etched thickness of the dye resist layer was 37.5 mm and the number of pieces of foreign matter was 116 in the sample that underwent O₂ etching for 20 seconds (No. 3). As indicated by the results for No. 4 through No. 8, the etched thickness of the dye resist layer increased and the number of pieces of foreign matter decreased as the etching time increased.

It was confirmed that the number of pieces of foreign matter on dye resist can be decreased by performing O₂ etching, compared to a case in which etching is not performed, from the evaluation results shown in FIG. 2. It was also seen that the number of pieces of foreign matter became 100 or less when the etching time was 30 seconds or longer, and that favorable removal of foreign matter was enabled.

The method of the present embodiment irradiates a laser beam onto the photoresist layer 12 which is formed on the substrate 11 to form hole portions 13, then performs gas etching on the photoresist layer 12 thereafter. Foreign matter, which is generated when the laser beam is irradiated to form the hole portions 13, can be removed from the photoresist layer 12 by the gas etching. The present embodiment employs a dry etching technique to remove foreign matter. Therefore, the problem of seeping etching fluid, which occurs if wet etching is performed, does not occur, and foreign matter can be removed without damaging the substrate 11.

Next, a second embodiment of the present invention will be described. In the first embodiment, the laser beam was irradiated onto the photoresist layer 12 under the same laser exposure conditions to form the plurality of hole portions 13 (FIG. 1C). In this case, the depths of the formed hole portions 13 will riot become uniform, and comparatively large fluctuations are present in the depths of the hole portions 13. The second embodiment reduces the fluctuations in the depths of the hole portions 13 that occur in the method for forming a pattern of the first embodiment.

In the present embodiment, the amount of etching in the gas etching step (FIG. 1D and FIG. 1E) following the formation of the hole portions is determined based on the film thickness of the photoresist layer 12 at the positions of the hole portions 13 (hereinafter, referred to also as “residual film thickness at the hole portions”). For example, a step of measuring the residual film thickness at the hole portions is added after the hole portions 13 are formed. The residual film thickness at the hole portions 13 is calculated as the difference between the film thickness of the photoresist layer 12 prior to forming the hole portions (FIG. 1A) and the depths of the hole portions 13 after the hole portions are formed (FIG. 1C). The amount of etching during gas etching to remove foreign matter is determined based on the measured residual film thickness at the hole portions.

In the step of measuring the residual film thickness at the hole portions, the residual film thickness at the hole portions is measured at a certain number of measurement points, for example, 10 measurement points, from among the plurality of hole portions 13 which are formed in the photoresist layer 12. Alternatively, the residual film thickness at all of the hole portions may be measured. An average value of the residual film thickness at the hole portion measured at the plurality of measurement points is calculated, and the amount of etching is determined based on the average value. For example, the amount of etching is determined to be 1.05 times the average value of the residual film thickness at the hole portions in the case that an expected fluctuation in the residual film thickness at the hole portions with respect to the average residual film thickness at the hole portions is 10%.

In the case that the amount of etching is set to be 1.05 times the average value of the residual film thickness at the hole portions, if the fluctuation in the residual film thickness at the hole portions is 10% or less, the surface of the substrate 11 can be exposed by reducing the film thickness of the photoresist layer 12 for the amount of etching by performing gas etching. In such a case, the depths of the hole portions can be made uniform at a depth, which is the film thickness of the photoresist layer 12 formed on the substrate 11 decreased by the amount of etching by gas etching.

In the description above, the amount of etching was determined with respect to an expected fluctuation in the depths of the hole portions. Alternatively, the maximum value and the minimum value of the residual film thickness at the hole portions may be obtained, the difference between these values may be obtained as the amount of fluctuation in the residual film, and the amount of etching maybe determined based on the obtained amount of fluctuation. For example, the amount of etching may be set to a value greater than or equal to half the obtained amount of fluctuation greater than the average value of the residual film thickness at the hole portions. By determining the amount of etching in this manner, the surface of the substrate 11 can be exposed at the position of each of the hole portions 13.

As a further alternative, the maximum value of the residual film thickness at the hole portions may be obtained instead of obtaining the amount of fluctuation, and the amount of etching may be set to be the maximum value or greater. In this case as well, the surface of the substrate 11 can be exposed at the position of each of the hole portions 13. From experience, it is known that the fluctuation in the residual film thickness at the hole portions is less than 40% with respect to the average value of the residual film thickness at the hole portions. For this reason, the amount of etching may be set to be 1.2 times or greater than the average value of the residual film thickness at the hole portions. In this case as well, the surface of the substrate 11 can be exposed at the position of each of the hole portions 13, and the depths of the hole portions can be uniformized.

Note that the upper limit of the amount of etching is not particularly limited. However, the film thickness of the photoresist layer 12 will decrease as the amount of etching is increased, and the depth of the hole portions will also decrease accordingly. The upper limit of the amount of etching is determined as appropriate from the film thickness of the photoresist layer 12 which is formed on the substrate 11 and a desired depth of the hole portions. In addition, in the description above, the residual film thickness at the hole portions was actually measured and the amount of etching was determined based on the measurement results. However, the present invention is not limited to such a configuration. For example, the relationship among the laser exposure conditions, the depths of the hole portions formed thereby, and the fluctuation in the depths of the hole portions may be calibrated in advance, and the amount of etching may be determined employing the calibrated relationship.

In the present embodiment, the amount of etching when gas etching is administered to remove foreign matter is determined according to the residual film thickness of the hole portions after the hole portions are formed. By determining the amount of etching such that the surface of the substrate 11 is exposed at at least a portion of the plurality of hole portions 13, fluctuations in the depths of the hole portions 13 can be suppressed compared to cases in which gas etching is not performed, after the gas etching is completed (FIG. 1E). Particularly in the case that the amount of etching performed by the gas etching is determined such that the surface of the substrate 11 is exposed at all of the hole portions 13, the depths of the hole portions 13 can be made substantially uniform.

Next, a third embodiment of the present invention will be described. The present invention is related to a method for producing a substrate having a pattern of protrusions and recesses that employs a pattern of protrusions and recesses formed on a photoresist layer. The pattern of protrusions and recesses is formed on the photoresist layer 12 by the method for forming a pattern of the second embodiment. That is, the photoresist layer 12 is formed on a substrate 11 (FIG. 1A). A laser beam is focused on the surface of the photoresist structure having the photoresist layer 12 thereon, to form hole portions 13 (FIG. 1B and FIG. 1C). Next, gas etching is performed to remove foreign matter on the photoresist layer 12 (FIG. 1D and FIG. 1E). During the gas etching, the surface of the substrate 11 is exposed at the positions of the hole portions 13, to uniformize the depths of the hole portions 13.

FIG. 3A through FIG. 3D illustrate the steps of the method for producing the substrate having a pattern of protrusions and recesses. Following the gas etching step that removes foreign matter and uniformizes the depths of the hole portions 13, plasma etching is performed using the photoresist layer 12 as a mask (FIG. 3A), to form recesses 14 in the substrate 11 (FIG. 3B). A gas that includes SF₆ may be employed to perform plasma etching. Alternatively, a gas that includes SF₆ and CH₃ at a predetermined ratio may be employed to perform plasma etching. The recesses 14 can be formed in the surface of the substrate 11 at positions corresponding to the positions of the hole portions 13, by performing plasma etching using the photoresist layer 12 as a mask. The recesses 14 can be favorably formed, because gas etching is performed after the hole portions 13 are formed in order to remove foreign matter which is generated when the hole portions are formed, after the hole portions 13 are formed.

After the recesses 14 are formed, the photoresist layer 12 is etched within a vacuum using a predetermined gas (FIG. 3C), to remove the photoresist layer 12 that remains on the surface of the substrate 11 (FIG. 3D). If the substrate 11 is a silicon substrate, O₂ gas may be employed in this etching step. A substrate 11 (photoresist structure 10) having a pattern of protrusions and recesses on the surface thereof, by removing the photoresist layer 12. Fluctuations in the depths of the recesses 14 formed in the substrate 11 can be suppressed, by uniformizing the depths of the hole portions 13 in the step of removing foreign matter from the photoresist layer 12, which is administered prior to etching of the substrate 11.

The present inventors performed the step of removing foreign matter (FIGS. 1D and 1E) under a plurality of etching conditions, to confirm the influence that the amounts of etching (etching times) during the foreign matter removing step influenced fluctuations in the depths of the recesses 14 which are formed in the substrate 11. In these experiments, a silicon substrate (100) having a thickness of 0.5 mm was employed as the substrate 11. A dye material (oxonol dye) having a composition indicated by the chemical formula below was employed as the photoresist layer 12. 2 grams of the dye material was diluted in 100 ml of a TFP (Tetra Fluoro Propanol) solution, and coated onto the silicon substrate by the spin coat method. The thickness of the dye resist layer formed by the spin coat method was 110 nm.

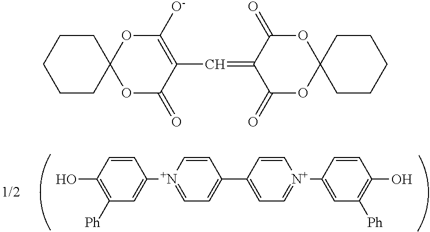

Next, laser exposure was performed on the surface of the dye resist structure having the dye resist layer thereon using NEO 1000 (wavelength: 405 nm, NA: 0.85) by Pulsetec Industrial, Co., Ltd. The laser exposure conditions were as follows.
Laser Feeding Pitch: 0.2 μm
Line Speed: 5 m/s
Recording Signal: 25 MHz Rectangular Waveform (Duty Ratio: 20%)
Laser Output: 3.5 mW

A plurality of samples of the dye resist structure were produced and underwent the laser exposure described above. O₂ plasma etching was administered onto each of the produced samples with an etching apparatus (EXAM by Shinko Seiki) for different etching times. The etching conditions for the O₂ plasma etching (first O₂ etching) were as follows.
Injection Power: 50 W
O₂ Gas Flow Rate: 100 sccm (Pressure: 18 Pa)
Etching Time: 40 seconds to 50 seconds (2 second increments), and 60 seconds

Plasma etching using SF₆ gas (foreign matter removing step) was administered to each sample (dye resist structure) following the first O₂ etching step, using an etching apparatus (EXAM by Shinko Seiki). The etching conditions were as follows.
Injection Power: 150 W
SF₆ Gas Pressure: 10 Pa
Etching Time: 10 seconds

O₂ plasma etching (ashing) was administered on each sample following plasma etching using SF₆. The etching conditions for the O₂ plasma etching (second O₂ etching) were as follows.
Injection Power: 180 W
O₂ Gas Flow Rate: 100 sccm (Pressure: 18 Pa)
Etching Time: 40 seconds

The surface of the silicon substrate, in which the recesses were formed, of each dye resist structure (each sample) was observed with an AFM (Atomic Force Microscope; Nanoscope V by Japan Veeco) following the second O₂ etching (ashing) step. The observation regions were 2 μm by 2 μm areas. The depths of dot shaped recesses formed in the silicon substrate and the fluctuations of the depths were measured by observing the surfaces of the silicon substrates.

As a comparative example, a similar observation was performed with respect to a sample that did not undergo the step of removing foreign matter nor the steps following thereafter, that is, a sample in a state which has undergone laser exposure (FIG. 1C). The surface of the dye resist layer of this sample was observed, to measure the depths of dot shaped recesses formed therein and to measure the fluctuations in the depths. In addition, a sample that did not undergo the foreign matter removal step and for which the etching time for SF₆ etching was 37 seconds was also prepared, and observation similar to that described above was performed for this sample as well. The etching conditions for the second O₂ etching step for this sample were the same as those described above. The surface of the silicon substrate of this sample was observed, to measure the depths of dot shaped recesses formed in the silicon substrate and the fluctuations of the depths.

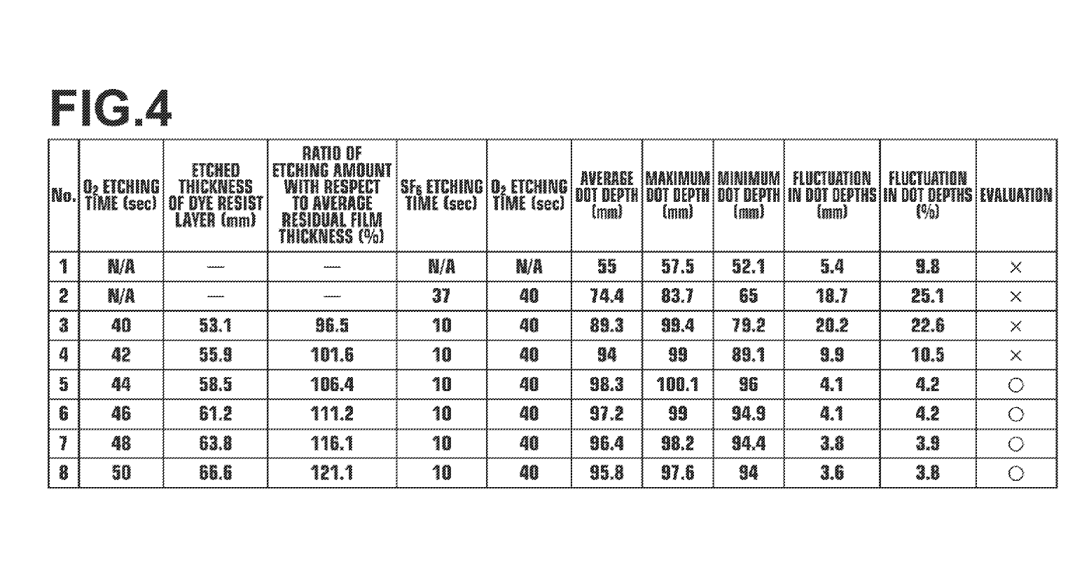

FIG. 4 shows the measurement results. The average depth of the hole portions in the dye resist layer (dot depth) in the sample that did not undergo foreign matter removal following laser exposure (No. 1 in the table of FIG. 4) was 55 mm. The maximum dot depth was 57.5 mm and the minimum dot depth was 52.1 mm. The amount of fluctuation, which is the difference between the maximum and minimum dot depths was 5.4 mm, and the fluctuation with respect to the average depth was 9.8%. As can be understood from the measurement results for this sample, the hole portions formed in the dye resist layer by irradiation of the laser beam had a fluctuation in depth of approximately 10% with respect to the average depth thereof.

In the sample on which SF₆ etching was performed without removing foreign matter (No. 2), the amount of fluctuation in dot depths was 18.7 mm with respect to the average dot depth (74.4 mm), and the fluctuation with respect to the average dot depth was 25.1%. As shown by this sample, the fluctuation in the depths of hole portions which are formed in the dye resist layer greatly influences the fluctuation in the depths of the recesses formed in the surface of the silicon substrate by etching using the dye resist layer as a mask.

No. 3 through. No. 8 show the measurement results for samples that underwent the first O₂ etching step, which corresponds to the foreign matter removing step, with varying etching times, then underwent SF₆ plasma etching, and then underwent the second O₂ etching step, which corresponds to ashing. The first O₂ etching time was short for the samples of No. 3 and No. 4, and the percentages of the amount of etching with respect to the average residual film thickness of the hole portions were 96.5% and 101.6%, respectively. In these samples, the fluctuations in the depths of the hole portions formed in the dye resist layer were comparatively large values (approximately 10%). Therefore, it was not possible to expose the surface of the substrate at the positions of all of the hole portions after performing the first O₂ etching step. Accordingly, it is considered that there were both portions at which the surface of the substrate was exposed, and portions at which the surface of the substrate was not exposed.

In the samples of No. 3 and No. 4, the fluctuations in the depths of the recesses formed in the surface of the silicon substrate by SF₆ etching using the dye resist layer as a mask were 22.6% and 10.5%, respectively. It is considered that the reason why the fluctuations were great in these cases is because there were both portions at which the surface of the substrate was exposed, and portions at which the surface of the substrate was not exposed at the time of SF₆ etching. Particularly focusing on the sample of No. 4, although the amount of etching during the first O₂ etching step is greater than the average residual film thickness at the hole portions, the fluctuation in the depths of the recesses which were formed in the surface of the silicon substrate was 10.5%, which is greater than the fluctuation in the depths of the hole portions (9.8%) formed in the dye resist layer of sample No. 1.

In contrast, in the samples of No. 5 through No. 8, the first O₂ etching step is administered at an amount of etching of 105% or greater with respect to the fluctuation in the depths of the hole portions (9.8%) formed in the dye resist layer. In these samples, the fluctuations in the depths of the recesses which were formed in the surfaces of the silicon substrates were 4.2%, 4.2%, 3.9%, and 3.8%, respectively. From these measurement results, it was understood that the fluctuations in dot depths can be suppressed to approximately 4%, by setting the amount of etching to 1.05 (105%) or greater with respect to the average residual film thickness in the case that the fluctuation in the depths of the hole portions in the dye resist layer is approximately 10%.

Particularly in the case that a dye resist layer is employed as a mask to etch a silicon substrate to form recesses, it is important to expose the surface of the substrate at the positions of hole portions prior to etching the silicon substrate. To this end, it is important to etch the dye resist layer with an amount of etching greater than or equal to the average depth of the hole portions formed in the dye resist to layer plus half the amount of fluctuation in depths during the first O₂ etching step which is performed to remove foreign matter.

In the present embodiment, the hole portions 13 are formed by irradiating a laser beam onto the photoresist layer 12 which is formed on the substrate 11. Then, gas etching is administered to remove foreign matter from the photoresist layer 12, and the substrate 11 is etched using the photoresist layer 12 as a mask. By adopting these steps, the recesses 14 can be formed in the surface of the substrate 11 with the pattern of the hole portions 13 which are formed in the photoresist layer 12. Favorable recesses which are not influenced by foreign matter can be formed in the substrate, because foreign matter is removed from the photoresist layer 12 by performing gas etching prior to etching the substrate 11. Particularly, fluctuation in the depths of the recesses formed in the substrate 11 can be suppressed, by determining the amount of etching during etching to remove foreign matter such that the surface of the substrate is exposed at the position of each of the hole portions.

Next, a fourth embodiment of the present invention will be described. The present embodiment is related to a method for producing a mold employing a substrate having a pattern of protrusions and recesses produced by the third embodiment. The method for producing a substrate of the third embodiment is employed to produce the substrate having the pattern of protrusions and recesses. That is, a photoresist layer 12 is formed on a substrate 11 (FIG. 1A). A laser beam is irradiated onto the photoresist layer 12, to form hole portions 13 (FIG. 1B and FIG. 1C). Next, gas etching is performed to remove foreign matter on the photoresist layer 12 (FIG. 1D and FIG. 1E). Thereafter, plasma etching is performed using the photoresist layer 12 as a mask, to form recesses 14 in the substrate 11 (FIG. 3A and FIG. 3B). Then, ashing is performed to remove the photoresist layer 12 (FIG. 3C and FIG. 3D).

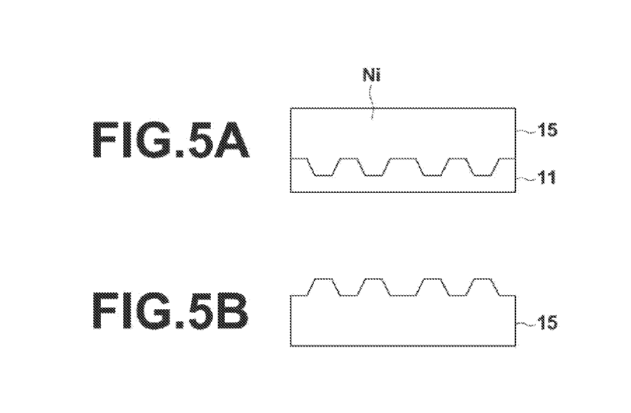

FIG. 5A and FIG. 5B illustrate the steps of a method for producing a mold having a pattern of protrusions and recesses. Following the ashing step, a metal layer 15 is deposited on the surface of the substrate 11 on which the pattern of protrusions and recesses is formed (FIG. 5A). In this step, for example, a thin electrically conductive film is formed on the substrate 11, the substrate is placed in a predetermined plating fluid, and an electroplating process is administered, to form the metal layer 15 having a predetermined thickness on the substrate 11. A metal mold, onto which the pattern of protrusions and recesses formed on the substrate 11 has been transferred, is obtained by separating the metal layer 15 from the substrate 11 (FIG. 5B). Nickel may be employed as the material of the metal mold, for example.

A favorable pattern of protrusions and recesses which is not influenced by foreign matter can be transferred onto the surface of the metal mold during production thereof, because foreign matter, which is generated when the hole portions 13 are formed by irradiating the laser beam onto the photoresist layer 12, is removed by gas etching. In addition, fluctuation in the pattern height (pattern depth) can be suppressed, by appropriately setting the amount of etching during foreign matter removal such that gas etching exposes the surface of the substrate 11 at the hole portions 13.

Note that the fourth embodiment was described as a case in which the pattern of protrusions and recesses is formed on the substrate 11, and a photoresist structure 10 (substrate 11), from which the photoresist layer 12 was removed by ashing, is employed as an original plate to transfer the pattern of protrusions and recesses. However, the present invention is not limited to such a configuration. For example, a photoresist structure 10 (FIG. 1E) produced by irradiating a laser beam on a photoresist layer 12 to form hole portions 13 and then administering gas etching to remove foreign matter may be employed as an original plate to transfer a pattern of protrusions and recesses. In this case, fluctuations in the pattern heights of the pattern of protrusions and recesses which is transferred can be suppressed, by uniformizing the depths of the hole portions 13 during etching to remove foreign matter.

In addition, the third embodiment was described as a case in which plasma etching is performed to form the recesses 14 in the substrate 11, then ashing is performed to remove the photoresist layer 12. However, the present invention is not limited to such a configuration. For example, the ashing step may be omitted. For example, in the fourth embodiment, the photoresist structure 10 on which the photoresist layer 12 remains as illustrated in FIG. 3B may be employed as the original plate to transfer a pattern of protrusions and recesses onto a mold. The material of the mold is not limited to metal, and transfer of the pattern of protrusions and recesses is not limited to an electroplating process.

With respect to the photoresist layer, the above were described as cases in which oxonol dye having the chemical formula described above is employed. However, the photoresist layer is not limited to the dye represented by the chemical formula described above. For example, a dye represented by the following chemical formula may be employed as the material of the photoresist layer.

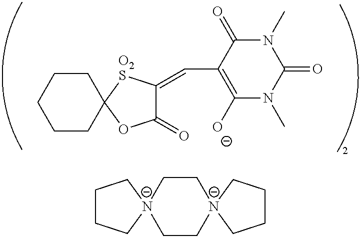

Preferred embodiments of the present invention have been described above. However, the method for forming a pattern, the method for producing a substrate, and the method for producing a mold of the present invention are not limited to the above embodiments. Various changes and modifications to the embodiments described above are encompassed within the scope of the present invention.

What is claimed is:

1. A method for forming a pattern, comprising the steps of:
forming a photoresist layer formed by organic dye, which is capable of deformation in a heat mode, on a substrate;
forming hole portions by irradiating a laser beam onto the photoresist layer, the hole portions being formed in the photoresist layer at portions onto which the laser beam is irradiated; and
etching the photoresist layer within a vacuum using a predetermined gas following the step of forming the hole portions.

2. The method for forming a pattern as defined in claim 1, wherein:
the amount of etching performed during the etching step is determined according to the thickness of the photoresist layer at the hole portions.

3. The method for forming a pattern as defined in claim 2, further comprising:
a measuring step that measures the thickness of the photoresist layer at the hole portions; and wherein:
the amount of etching is determined based on the thickness measured in the measuring step.

4. The method for forming a pattern as defined in claim 3, wherein:
the thickness of the photoresist layer at the hole portions is measured at a plurality of measurement points in the measuring step;
an average value of the thicknesses of the photoresist layer measured at the plurality of measurement points is calculated; and
the amount of etching is determined based on the calculated average value.

5. The method for forming a pattern as defined in claim 4, wherein:
the amount of etching is determined to be a value 1.05 times the average value or greater.

6. The method for forming a pattern as defined in claim 4, wherein:
the amount of etching is determined to be a value 1.2 times the average value or greater.

7. The method for forming a pattern as defined in claim 4, wherein:
the fluctuation in the thickness of residual film is calculated based on the maximum value and the minimum value of the thickness of the photoresist layer measured at the plurality of measurement points in the measuring step; and
wherein:
the amount of etching is determined based on the average value and the fluctuation in the thickness of residual film.

8. The method for forming a pattern as defined in claim 3, wherein:
the measuring step measures the thickness of the photoresist layer at the hole portions at a plurality of measurement points; and
the amount of etching is determined based on the maximum value of the thickness of the photoresist layer measured at the plurality of measurement points.

9. The method for forming a pattern as defined in claim 1, wherein:
the substrate is a Si substrate; and
the predetermined gas contains O₂.

10. The method for forming a pattern as defined in claim 1, wherein:
foreign matter, which is generated by the laser beam being irradiated onto the photoresist layer when the hole portions are formed, is removed by the step of etching the photoresist layer.

11. A method for producing a substrate having a pattern of protrusions and recesses, comprising the steps of:
forming a photoresist layer formed by organic dye, which is capable of deformation in a heat mode, on a substrate;
forming hole portions by irradiating a laser beam onto the photoresist layer, the hole portions being formed in the photoresist layer at portions onto which the laser beam is irradiated;
exposing the surface of the substrate at the hole portions by etching the photoresist layer within a vacuum using a predetermined gas following the step of forming the hole portions; and
forming a pattern of protrusions and recesses on the surface of the substrate by performing plasma etching using the photoresist layer as a mask, following the step of exposing the surface of the substrate.

12. The method for producing a substrate having a pattern of protrusions and recesses as defined in claim 11, further comprising:
removing the photoresist layer from the substrate by etching the photoresist layer within a vacuum using a predetermined gas, following the step of forming the pattern of protrusions and recesses on the surface of the substrate.

13. The method for producing a substrate having a pattern of protrusions and recesses as defined in claim 11, wherein:
the substrate is a Si substrate; and
a gas that contains SF₆ is used to perform plasma etching in the step of forming the pattern of protrusions and recesses on the surface of the substrate.

14. A method for producing a mold, comprising the steps of:
forming a photoresist layer formed by organic dye, which is capable of deformation in a heat mode, on a substrate, to produce a photoresist structure;
forming hole portions by irradiating a laser beam onto the surface of the photoresist structure toward the side of the photoresist layer, the hole portions being formed in the photoresist layer at portions onto which the laser beam is irradiated;
etching the surface of the photoresist structure toward the side of the photoresist layer within a vacuum using a predetermined gas following the formation of the hole portions, to remove foreign matter which is generated by the laser beam being irradiated onto the photoresist layer when the hole portions are formed; and
transferring a pattern of protrusions and recesses formed on the original plate to the mold employing the photoresist structure as an original plate.

15. The method for producing a mold as defined in claim 14, wherein:
the surface of the substrate is exposed at the hole portions by the step of etching the photoresist layer; and
the method further comprises the step of:
forming a pattern of protrusions and recesses on the surface of the substrate by performing plasma etching using the photoresist layer as a mask, between the step of etching the photoresist layer and the step of transferring the pattern of protrusions and recesses to the mold.

16. The method for producing a mold as defined in claim 15, further comprising:
a step that etches the photoresist layer within a vacuum using a predetermined gas to remove the photoresist layer from the substrate, between the step of forming the pattern of protrusions and recesses on the surface of the substrate and the step of transferring the pattern of protrusions and recesses to the mold.
